(19) United States
(12) Patent Application Publication
(10) Pub. No.: US 2016/0177124 A1
(43) Pub. Date: Jun. 23, 2016

(54) CO-CROSSLINKER SYSTEMS FOR ENCAPSULATION FILMS COMPRISING ETHYLENE GLYCOL DI(METH)ACRYLATE COMPOUNDS

(71) Applicants: Daniel ULBRICHT, Darmstadt (DE); Marcel HEIN, Niedernberg (DE); Frank KLEFF, Bruchkoebel-Oberissigheim (DE); Stephanie SCHAUHOFF, Langen (DE); Juergen OHLEMACHER, Bad Vilbel (DE)

(72) Inventors: Daniel ULBRICHT, Darmstadt (DE); Marcel HEIN, Niedernberg (DE); Frank KLEFF, Bruchkoebel-Oberissigheim (DE); Stephanie SCHAUHOFF, Langen (DE); Juergen OHLEMACHER, Bad Vilbel (DE)

(73) Assignee: Evonik Degussa GmbH, Essen (DE)

(21) Appl. No.: 14/973,145

(22) Filed: Dec. 17, 2015

(30) Foreign Application Priority Data
Dec. 19, 2014 (EP) 14199266

(51) Int. Cl. C09D 139/04; H01L 31/0203; C08F 226/06

(52) U.S. Cl. CPC C09D 139/04; C08F 226/06; H01L 31/0203

(57) ABSTRACT

A first composition (A) contains (i) at least one compound (I) selected from the group consisting of triallyl isocyanurate, and triallyl cyanurate, wherein the compound (I) is preferably triallyl isocyanurate, and (ii) at least one ethylene glycol di(meth)acrylate compound. In addition, a second composition (B) contains the first composition (A) and at least one polyolefin copolymer. Composition (B) can be used for production of a film for encapsulation of an electronic device, especially a solar cell.

### BACKGROUND OF THE INVENTION

1. Field of the Invention

The present invention relates to a first composition (A) comprising (i) at least one compound (I) selected from the group consisting of triallyl isocyanurate, triallyl cyanurate, wherein the compound (I) is preferably triallyl isocyanurate, and (ii) at least one ethylene glycol di(meth)acrylate compound. In addition, the present invention also relates to a second composition (B) comprising the first composition (A) and at least one polyolefin copolymer. Finally, the present invention relates to the use of the composition (B) for production of a film for encapsulation of an electronic device, especially a solar cell.

2. Discussion of the Background

Photovoltaic modules (photovoltaic=“PV”) typically consist of a layer of symmetrically arranged silicon cells welded into two layers of a protective film. This protective film is itself stabilized in turn by a “backsheet” on its reverse side and a “frontsheet” on its front side. The backsheet and frontsheet may either be suitable polymer films or consist of glass. The function of the encapsulation material is essentially to protect the PV module from weathering effects and mechanical stress, and for that reason the mechanical stability of the particular encapsulation material is an important property. In addition, good encapsulation materials exhibit a rapid curing rate, high gel content, high transmission, low tendency to temperature- and heat-induced discolouration and high adhesion (i.e. a low propensity to UV-induced delamination).

The encapsulation materials described for this purpose in the related art (for example WO 2008/036708 A2) are typically based on materials such as silicone resins, polyvinyl butyral resins, ionomers, polyolefin films or ethylene-vinyl acetate copolymers (“EVA”).

Processes for producing such encapsulation films are familiar to those skilled in the art (EP 1 164 167 A1). In these processes the crosslinkers, together with a polyolefin copolymer (and possibly further additives), are homogeneously mixed in an extruder for example, and then extruded to give a film. The process described in EP 1 164 167 A1 relates to EVA but is also applicable to films made of other materials, for example those mentioned hereinabove.

The encapsulation of the silicon cells is typically performed in a vacuum lamination oven (EP 2 457 728 A1). To this end, the layer structure of the PV module is prepared and initially heated up gradually in a lamination oven (consisting of two chambers separated by a membrane). This softens the polyolefin copolymer (for example EVA). The oven is simultaneously evacuated to remove the air between the layers. This step is the most critical and takes between 4 and 6 minutes. Subsequently, the vacuum is broken via the second chamber, and the layers of the module are welded to one another by application of pressure. Heating is simultaneously continued up to the crosslinking temperature, the crosslinking of the film then taking place in this final step.

The use of EVA in particular is standard in the production of encapsulation films for solar modules. However, EVA also has a lower specific electrical resistance ρ than polyolefin films for example. This makes the use of EVA films as encapsulation material less attractive, since it is specifically encapsulation materials having high specific electrical resistance ρ that are desired.

This is because, in the case of PV modules, what is called the “PID” effect (PID=potential-induced degradation) is currently a major quality problem. The term “PID” is understood to mean a voltage-related performance degradation caused by what are called “leakage currents” within the PV module.

Causes of the damaging leakage currents are, as well as the setup of the solar cell, the voltage level of the individual PV modules with respect to the earth potential—in the case of most unearthed PV systems, the PV modules are subjected to a positive or negative voltage. PID usually occurs at a negative voltage relative to earth potential and is accelerated by high system voltages, high temperatures and high air humidity. As a result, sodium ions migrate out of the cover glass of the PV module to the interface of the solar cell and cause damage (“shunts”) there, which lead to performance losses or even to the total loss of the PV module.

The risk of occurrence of a PID effect can be distinctly reduced by increasing the specific electrical resistance ρ of the encapsulation films.

The specific electrical resistance ρ or else volume resistivity (also abbreviated hereinafter to “VR”) is a temperature-dependent material constant. It is utilized to calculate the electrical resistivity of a homogeneous electrical conductor. Specific electrical resistance is determined in accordance with the invention by means of ASTM-D257.

The higher the specific electrical resistance ρ of a material, the less photovoltaic modules are prone to the PID effect. A significant positive effect in increasing the specific electrical resistance ρ of encapsulation films is therefore the increase in the lifetime and efficiency of PV modules.

The related art discusses the problem of the PID effect in connection with encapsulation films for PV modules in CN 103525321 A. This document describes an EVA-based film for encapsulation of solar cells, which comprises triallyl isocyanurate (“TAIC”) and trimethylolpropane trimethacrylate (“TMPTMA”) as co-crosslinkers and, as further additives, preferably comprises a polyolefin ionomer and a polysiloxane for hydrophobization. This film exhibits a reduced PID effect. However this film has the disadvantage that polyolefin ionomers are relatively costly. Polysiloxanes moreover have an adverse effect on adhesion properties. In addition, the examples do not give any specific information as to the improvements achievable with particular concentrations.

A crosslinker combination of TAIC and TMPTMA is also described by JP 2007-281135 A. The TMPTMA here brings about acceleration of the crosslinking reaction and hence leads to elevated productivity.

JP 2012-067174 A and JP 2012-087260 A respectively describe an EVA-based and a polyolefin-based encapsulation film for solar cells, comprising, as well as TAIC, for example, ethylene glycol dimethacrylate, neopentyl glycol dimethacrylate, hexane-1,6-diol dimethacrylate as crosslinker. These co-crosslinkers slow the crosslinking reaction at the start somewhat and as a result increase the processing time window. The problem of specific resistance is not addressed. JP 2009-135200 A likewise describes crosslinkers comprising TAIC and various (meth)acrylate derivatives of polyfunctional alcohols, improved heat resistance coupled with a reduced tendency for delamination of the EVA-based encapsulation being described in this case.

JP 2007-281135 A and JP 2007-305634 A describe crosslinker combinations of TAIC and trimethylolpropane triacrylate (“TMPTA”) for use in the production of multilayer co-extruded EVA encapsulation films for solar cells.

Similar combinations of crosslinkers for solar cell encapsulation films are described, for example, by JP 2013-138094 A, JPH11-20094, JPH11-20095, JPH11-20096, JPH11-20097, JPH11-20098, JPH11-21541, CN 102391568 A, CN 102504715 A, CN 102863918 A, CN 102911612 A, CN 103045105 A, CN 103755876 A, CN 103804774 A, US 2011/0160383 A1, WO 2014/129573 A1.

There is accordingly a need for novel co-crosslinker systems, especially for production of encapsulation films for solar cells, which result in a markedly increased electrical resistance compared to films crosslinked in accordance with the related art, and thus lead to a reduction in the PID risk when employed in photovoltaic modules.

### SUMMARY OF THE INVENTION

The problem addressed by the present invention was therefore that of providing novel compositions which can be used for production of films having maximum specific electrical resistance ρ and which are therefore particularly suitable for encapsulation of electronic devices, for example solar cells. These compositions should additionally be usable in the established processes and should not substantially increase the costs of the films. In particular, said compositions should not exhibit the disadvantages observed for the co-crosslinker systems of the related art and in particular for the compositions cited in CN 103525321 A.

It has now been found that, surprisingly, it is possible with the aid of particular compositions to obtain an encapsulation film for solar cells that meets these requirements. The compositions found here considerably increase volume resistivity, even when comparatively small amounts are employed, without adversely affecting other film properties. The films exhibit excellent processibility, high transparency and excellent UV and heat ageing properties.

The present invention relate to a composition (A), comprising:

(i) at least one compound (I) selected from the group consisting of triallyl isocyanurate, and triallyl cyanurate; and

(ii) at least one compound of the chemical structure (II) with

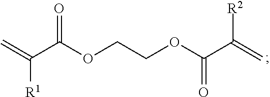

wherein R¹, R² are each independently H or methyl,

and wherein the proportion of all the compounds of the chemical structure (II) in the composition (A), based on all the compounds (I) in the composition (A), is in the range of 0.01 mol % to 13.5 mol %.

In another embodiment, the present invention relates to a composition (B), comprising:

at least one polyolefin copolymer; and

a composition (A) as above.

The present invention also provides a film for encapsulation of an electronic device, comprising: the above composition (B) in crosslinked form.

Moreover, the present invention provides a method for encapsulating an electronic device, comprising:

contacting said electronic device with the above composition (B) and crosslinking said composition (B).

### DETAILED DESCRIPTION OF THE INVENTION

Any ranges mentioned herein below include all values and subvalues between the lowest and highest limit of this range.

The co-crosslinker systems according to the present invention can surprisingly be used for producing films for encapsulating electronic devices, for example solar cells, having a high specific resistance.

Accordingly, the co-crosslinker system according to the invention is a composition (A) comprising (i) at least one compound (I) selected from the group consisting of triallyl isocyanurate, triallyl cyanurate; and

(ii) at least one compound of the chemical structure (II) with

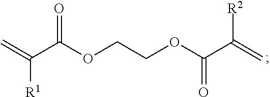

where R¹, R² are each independently H or methyl, and wherein the proportion of all the compounds of the chemical structure (II) in the composition (A), based on all the compounds (I) in the composition (A), is in the range of 0.01 mol % to 13.5 mol %.

A compound of the chemical structure (II) is also referred to in the context of the invention as “ethylene glycol di(meth)acrylate compound”.

In a preferred embodiment, the compound (I) in the composition (A) is triallyl isocyanurate.

In a further preferred embodiment, R¹ and R² are the same; even more preferably, R¹=R²=methyl.

The ratio of the amount of compounds of the chemical structure (II) in the composition (A) according to the invention to the compounds (I) in the composition (A) according to the invention is in the range of 0.01 mol % to 13.5 mol %, especially in the range of 0.05 mol % to 12.0 mol %, preferably in the range of 0.1 mol % to 8.5 mol %, even more preferably 1.0 mol % to 8.1 mol %, most preferably 2.5 mol % to 5.2 mol %.

This is because it has been found that, surprisingly, compositions (A) in which this ratio of compounds of the chemical structure (II) in the composition (A) according to the invention to the compounds (I) in the composition (A) according to the invention is observed to lead to production of films having particularly high specific resistance.

This was especially surprising in the light of the related art, for instance JP 2012-067174 A and JP 2012-087260 A, which describe only general compositions having a relatively high proportion of a dimethacrylate compound and do not discuss the problem of the PID effect at all.

In contrast, within the scope of the present invention, it has been found that an increase in specific resistance is discernible particularly even in the case of addition of small amounts of the compounds of the chemical structure (II), or in other words when the proportion of all compounds of the chemical structure (II) based on all compounds (I) in the composition (A) is 0.01 mol %. With regard to economic use of the compounds of the chemical structure (II), on the other hand, a proportion of all compounds of the chemical structure (II) in the composition (A) based on all compounds (I) in the composition (A) of 13.5 mol % is a preferred upper limit. Even more preferably, in the composition (A), the proportion of all compounds of the chemical structure (II) based on all compounds (I) is 0.1 mol % to 10 mol %, even more preferably 2.5 mol % to 8.5 mol %, most preferably 5.2 mol % to 8.1 mol %.

In a particularly preferred embodiment of the composition (A) according to the invention, particularly high specific resistance values are attained. This is the case when the compound (I) used is triallyl isocyanurate “TAIC”) and the compound of the chemical structure (II) used is ethylene glycol dimethacrylate (=“EGDMA”) (the latter being a compound of the chemical structure (II) in which R¹=R²=methyl), in which case the molar ratio of EGDMA to TAIC in the composition (A) is especially 2.5 mol % to 8.1 mol %, more preferably 5.2 mol %.

The present co-crosslinker systems are preferably used for production of films for encapsulation of electronic devices, for example solar cells in PV modules.

These co-crosslinker systems are typically used together with polyolefin copolymers.

The present invention accordingly also relates to a composition (B) comprising at least one polyolefin copolymer and the composition (A) according to the invention.

Polyolefin copolymers usable in accordance with the invention are known to those skilled in the art and are described, for instance, in WO 2008/036708 A2 and JP 2012-087260.

More particularly, in accordance with the invention, polyolefin copolymers used are ethylene/α-olefin interpolymers, the term “interpolymer” meaning that the polyolefin copolymer in question has been prepared from at least two different monomer units. Thus, the term “interpolymer especially includes polyolefin copolymers formed from exactly two monomer units, but also terpolymers (for example ethylene/propylene/1-octene, ethylene/propylene/butene, ethylene/butene/1-octene, ethylene/butene/styrene) and tetrapolymers.

Useful polyolefin copolymers in accordance with the invention are especially ethylene/α-olefin copolymers which preferably do not have any further monomer units aside from ethylene and the α-olefin, the “α-olefin” in the context of the invention preferably being selected from the group consisting of propene, 1-butene, 4-methyl-1-pentene, 1-hexene, 1-octene, 1-decene, 1-dodecene, 1-tetradecene, 1-hexadecene, 1-octadecene, 3-cyclohexyl-1-propene, vinylcyclohexane, acrylic acid, methacrylic acid, norbornene, styrene, methylstyrene, vinyl acetate.

Even more preferably, the polyolefin copolymer according to the invention in the composition (B) is an ethylene-vinyl acetate copolymer.

If polyolefin copolymers used are ethylene/a-olefin interpolymers, these especially have a-olefin content in the range of 15% to 50% by weight, based on the total weight of the ethylene/α-olefin interpolymer. Preferably, the α-olefin content is in the range of 20% to 45% by weight, more preferably in the range of 25% to 40% by weight, even more preferably 26% to 34% by weight, most preferably 28% to 33% by weight, based in each case on the total weight of the ethylene/α-olefin interpolymer.

In the preferred embodiment in which the polyolefin copolymer is an ethylene-vinyl acetate copolymer, the ethylene-vinyl acetate copolymer especially has a vinyl acetate content in the range of 15% to 50% by weight, based on the total weight of the ethylene-vinyl acetate copolymer. Preferably, the vinyl acetate content in that case is in the range of 20% to 45% by weight, more preferably in the range of 25% to 40% by weight, even more preferably 26% to 34% by weight, most preferably 28% to 33% by weight, based in each case on the total weight of the ethylene/vinyl acetate interpolymer.

The α-olefin content, especially the content of vinyl acetate in the case of the ethylene/vinyl acetate copolymer, is determined here by the method described in ASTM D 5594:1998 [“Determination of the Vinyl Acetate Content of Ethylene-Vinyl Acetate (EVA) Copolymers by Fourier Transform Infrared Spectroscopy”].

There is no particular restriction here in the proportion of the composition (A) encompassed by the composition (B). The proportion of the composition (A) in the composition (B) is especially in the range from 0.05% to 10% by weight, preferably in the range from 0.1% to 5% by weight, more preferably 0.2% to 3% by weight, even more preferably 0.3% to 1% by weight, especially preferably 0.5% by weight, based in each case on the mass of all the polyolefin copolymers encompassed by the composition (B).

According to the invention, the composition (B) is suitable for production of an encapsulation film for electronic devices, for example solar cells. For this purpose, it is subjected to a crosslinking reaction in the course of solar module lamination.

To initiate the crosslinking reaction, it is customary to use initiators, i.e. free-radical formers activatable by means of heat, light, moisture or electron beams.

In a preferred embodiment of the present invention, the composition (B) therefore also comprises an initiator selected from the group consisting of peroxidic compounds, azo compounds, photoinitiators. More preferably, the initiator is selected from the group consisting of peroxidic compounds, azo compounds. Examples of these are described in the “Encyclopedia of Chemical Technology 1992, 3rd Edition, Vol. 17, pages 27-90”.

Peroxidic compounds are especially organic peroxides, which are in turn selected from the group consisting of dialkyl peroxides, diperoxy ketals, peroxycarboxylic esters, peroxycarbonates.

Dialkyl peroxides are especially selected from the group consisting of dicumyl peroxide, di-tert-butyl peroxide, di-tert-hexyl peroxide, tert-butylcumyl peroxide, iso-propylcumyl tert-butyl peroxide, tert-hexylcumyl peroxide, 2,5-dimethyl-2,5-di(tert-butylperoxy)hexane, 2,5-dimethyl-2,5-di(tert-amylperoxy)hexane, 2,5-dimethyl-2,5-di(tert-butylperoxy)-hex-3-yne, 2,5-dimethyl-2,5-di(tert-amylperoxy)-hex-3-yne, α,α-di[(tert-butylperoxy)-iso-propyl]benzene, di-tert-amyl peroxide, 1,3,5-tri[(tert-butylperoxy)isopropyl]benzene, 1,3-dimethyl-3-(tert-butylperoxy)butanol, 1,3-dimethyl-3-(tert-amylperoxy)butanol, iso-propylcumyl hydroperoxide.

Diperoxy ketals are especially selected from the group consisting of 1,1-di(tert-butylperoxy)-3,3,5-trimethylcyclohexane, 1,1-di(tert-amylperoxy)cyclohexane, 1,1 -di(tert-butylperoxy)cyclohexane, n-butyl 4,4-di(tert-amylperoxy)valerate, ethyl 3,3 -di(tert-butylperoxy)butyrate, 2,2-di(tert-butylperoxy)butane, 3,6,6,9,9-pentamethyl-3-ethoxycarbonylmethyl-1,2,4,5-tetraoxacyclononane, 2,2-di(tert-amylperoxy)propane, n-butyl 4,4-bis(tert-butylperoxy)valerate.

Peroxycarboxylic esters are especially selected from the group consisting of tert-amyl peroxyacetate, tert-butyl peroxy-3,5,5-trimethylhexanoate, tert-amyl peroxybenzoate, tert-butyl peroxyacetate, tert-butyl peroxybenzoate, OO-tert-butyl monoperoxysuccinate, OO-tert-amyl monoperoxysuccinate.

Peroxycarbonates are especially selected from the group consisting of tert-butylperoxy-2-ethylhexylcarbonate, tert-butyl peroxy-iso-propylcarbonate, tert-amyl peroxy-2-ethylhexylcarbonate, tert-amyl peroxybenzoate. A preferred peroxycarbonate is tert-butyl peroxy-2-ethylhexylcarbonate (“TBPEHC”).

The azo compound is preferably selected from the group consisting of 2,2′-azobis(2-acetoxypropane), 1,1′-azodi(hexahydrobenzonitrile).

More preferably, the initiator is selected from the group consisting of 2,5-dimethyl-2,5-di(tert-butylperoxy)hexane, tert-butyl peroxy-2-ethylhexylcarbonate, tert-butyl peroxy-3,5,5-trimethylhexanoate, 1,1-di(tert-butylperoxy)-3,5,5-trimethylcyclohexane, tert-amyl peroxy-2-ethylhexylcarbonate; most preferred is the initiator tert-butyl peroxy-2-ethylhexylcarbonate (“TBPEHC”).

There is no particular restriction in the mass of the peroxidic compound or of the azo compound, preferably of the peroxidic compound, which is used, based on the mass of the polyolefin copolymer. The peroxidic compound or the azo compound, preferably the peroxidic compound, is especially used in an amount of 0.05% to 10% by weight, preferably 0.1% to 5% by weight, more preferably 0.5% to 2% by weight, based in each case on the mass of all the polyolefin copolymers encompassed by the composition (B).

Photoinitiators are especially selected from the group consisting of benzophenone, benzanthrone, benzoin, benzoin alkyl ethers, 2,2-diethoxyacetophenone, 2,2-dimethoxy-2-phenylacetophenone, p-phenoxydichloroacetophenone, 2-hydroxycyclohexylphenone, 2-hydroxyisopropylphenone, 1-phenylpropanedione 2-(ethoxycarbonyl)oxime.

The photoinitiator is especially used in an amount of 0.05% to 10% by weight, preferably 0.1% to 5% by weight, more preferably 0.2% to 3% by weight, even more preferably 0.25% to 1% by weight, based in each case on the mass of all the polyolefin copolymers encompassed by the composition (B).

In a further preferred embodiment of the present invention, the composition (B) also comprises at least one further compound selected from the group consisting of crosslinkers, silane coupling agents, antioxidants, ageing stabilizers, metal oxides, metal hydroxides, white pigments, particular preference being given to using silane coupling agents as the further compound.

The term “further compound” in the context of the invention implies that this compound is not triallyl isocyanurate, triallyl cyanurate or a compound of the chemical structure (II).

Crosslinkers here are preferably selected from the group consisting of trimethylolpropane triacrylate, trimethylolpropane trimethacrylate, divinylbenzene, acrylates and methacrylates of polyhydric alcohols. Acrylates and methacrylates of polyhydric alcohols are especially selected from the group consisting of diethylene glycol di(meth)acrylate, polyethylene glycol di(meth)acrylate, neopentyl glycol di(meth)acrylate, hexane-1,6-diol di(meth)acrylate, nonane-1,9-diol di(meth)acrylate, decane-1,10-diol di(meth)acrylate.

There is no particular restriction here in the proportion of the crosslinkers encompassed by the composition (B). The proportion of the crosslinkers in the composition (B) is especially 0.005% to 5% by weight, preferably 0.01% to 3% by weight, more preferably 0.05% to 3% by weight, even more preferably 0.1% to 1.5% by weight, based in each case on the mass of all the polyolefin copolymers encompassed by the composition (B).

Silane coupling agents usable in accordance with the invention in the composition (B) include all silanes having an unsaturated hydrocarbyl radical and a hydrolysable radical (described, for instance, in EP 2 436 701 B1, U.S. Pat. No. 5,266,627).

Unsaturated hydrocarbyl radicals are especially selected from the group consisting of vinyl, allyl, isopropenyl, butenyl, cyclohexenyl, γ-(meth)acryloyloxyallyl.

Hydrolysable radicals are especially selected from the group consisting of hydrocarbyloxy, hydrocarbonyloxy, hydrocarbylamino. Preferably, the hydrolysable radical is selected from the group consisting of methoxy, ethoxy, formyloxy, acetoxy, propionyloxy, alkylamino, arylamino.

Preferably, the silane coupling agent is selected from the group consisting of: vinyltriethoxysilane, vinyltris-(β-methoxyethoxy)silane, vinyltriacetoxysilane, γ-acryloyloxypropyltrimethoxysilane, γ-methacryloyloxypropyltrimethoxysilane, N-(β-aminoethyl)-γ-aminopropyltrimethoxysilane, N-(β-aminoethyl)-γ-aminopropylmethyldimethoxysilane, γ-aminopropyltriethoxysilane, γ-glycidoxypropyltrimethoxysilane, γ-mercaptopropyltriethoxysilane, γ-chloropropyltrimethoxysilane, β-(3,4-ethoxycyclohexy)ethyltrimethoxysilane, γ-mercaptopropyltrimethoxysilane. Particular preference is given to using, as a silane coupling agent, γ-methacryloyloxypropyltrimethoxysilane (abbreviated to “KBM”).

There is no particular restriction here in the proportion of the silane coupling agent encompassed by the composition (B). The proportion of all the silane coupling agents encompassed by the composition (B) is especially 0.05% to 5% by weight, preferably 0.1% to 2% by weight, based in each case on the mass of all the polyolefin copolymers encompassed by the composition (B).

Antioxidants in the context of the invention are preferably selected from the group consisting of phenolic antioxidants, phosphorus antioxidants.

Phenolic antioxidants are especially selected from the group consisting of 4-methoxyphenol, 2,6-di-tert-butyl-4-methylphenol, tert-butylhydroquinone, stearyl β-di-tert-butyl-4-hydroxyphenyl)propionate, pentaerythrityl tetrakis[3-(3,5-di-tert-butyl-4-hydroxyphenyl)propionate], hexadecyl 3,5-di-tert-butyl-4-hydroxybenzoate.

Phosphorus antioxidants are especially selected from the group consisting of triphenyl phosphite, tris(nonylphenyl) phosphite, distearylpentaerythritol diphosphite, tetra(tridecyl)-1,1,3-tris-(2-methyl-5-tert-butyl-4-hydroxyphenyl)butane diphosphate, tetrakis(2,4-di-tert-butylphenyl)-4,4-biphenyl diphosphonite.

There is no particular restriction here in the proportion of the antioxidants encompassed by the composition (B). The proportion of all the antioxidants encompassed by the composition (B) is especially 0.01% to 0.5% by weight, preferably 0.05% to 0.3% by weight, based in each case on the mass of all the polyolefin copolymers encompassed by the composition (B).

Ageing stabilizers in the context of the invention are especially selected from the group of the “hindered amine light stabilizers” (=“HALS”) and the UV absorbers.

HALS stabilizers in the context of the invention are especially compounds having at least one 2,2,6,6-tetramethyl-4-piperidyl radical, where the nitrogen atom at the 1 position of the piperidyl radical bears an H, an alkyl group or an alkoxy group.

Preference is given to HALS stabilizers selected from the group consisting of bis(2,2,6,6-tetramethyl-4-piperidyl) sebacate, 1,2,2,6,6-pentamethyl-4-piperidyl sebacate,

bis(1,2,2,6,6-pentamethyl-4-piperidyl) sebacate, bis-(1-octyloxy-2,2,6,6-tetramethyl-4-piperidyl) sebacate, poly{(6-morpholino-S-triazine-2,4-diyl)[2,2,6,6-tetramethyl-4-piperidyl)imino]hexamethylene[(2,2,6,6-tetramethyl-4-piperidyl)imino]} having CAS Number 82451-48-7,

polymers of CAS Number 193098-40-7,

copolymer of dimethyl succinate and 1-(2-hydroxyethyl)-2,2,6,6-tetramethyl-4-piperidinol,

N,N′,N″,N′″“-tetrakis-{4,6-bis[butyl(N-methyl-2,2,6,6-tetramethylpiperidin-4-yl)amino]triazin-2-yl}-4,7-diazadecane-1,10-diamine having CAS Number 106990-43-6.

There is no particular restriction here in the proportion of the HALS stabilizers encompassed by the composition (B). The proportion of all the HALS stabilizers encompassed by the composition (B) is especially 0.01% to 0.5% by weight, preferably 0.05% to 0.3% by weight, based in each case on the mass of all the polyolefin copolymers encompassed by the composition (B).

UV absorbers are especially selected from the group consisting of 2-hydroxy-4-N-octoxybenzophenone, 2,4-di-tert-butylphenyl 3,5-di-tert-butyl-4-hydroxybenzoate, 2-hydroxy-4-methoxybenzophenone, 2,2-dihydroxy-4-methoxybenzophenone, 2-hydroxy-4-methoxy-4-carboxybenzophenone, 2-(2-hydroxy-3,5-di-tert-butylphenyl)benzotriazole, 2-(2-hydroxy-5-methylphenyl)benzotriazole, p-octylphenyl salicylate, 2-(4,6-diphenyl-1,3,5-triazin-2-yl)-5-[(hexyl)oxy]phenol, ethyl 2-cyano-3,3-diphenylacrylate.

There is no particular restriction here in the proportion of the UV absorbers encompassed by the composition (B). The proportion of all the UV absorbers encompassed by the composition (B) is especially 0.01% to 0.5% by weight, preferably 0.05% to 0.3% by weight, based in each case on the mass of all the polyolefin copolymers encompassed by the composition (B).

According to the invention, metal oxides are especially selected from the group consisting of alkali metal oxides, alkaline earth metal oxides, zinc oxide, preferably selected from the group consisting of magnesium oxide, zinc oxide.

There is no particular restriction here in the proportion of the metal oxides encompassed by the composition (B). The proportion of all the metal oxides encompassed by the composition (B) is especially 0.01% to 10% by weight, preferably 0.05% to 3% by weight, based in each case on the mass of all the polyolefin copolymers encompassed by the composition (B).

According to the invention, metal hydroxides are especially selected from the group consisting of alkali metal hydroxides, alkaline earth metal hydroxides, preferably selected from the group consisting of magnesium hydroxide, calcium hydroxide.

There is no particular restriction here in the proportion of the metal hydroxides encompassed by the composition (B). The proportion of all the metal hydroxides encompassed by the composition (B) is especially 0.01% to 10% by weight, preferably 0.05% to 3% by weight, based in each case on the mass of all the polyolefin copolymers encompassed by the composition (B).

White pigments in the context of the invention are especially selected from the group of titanium dioxide, zinc oxide, zinc sulphide, barium sulphate, lithopone.

There is no particular restriction here in the proportion of the white pigments encompassed by the composition (B). The proportion of all the white pigments encompassed by the composition (B) is especially 5% to 25% by weight, preferably 10% to 20% by weight, even more preferably 15% by weight, based in each case on the mass of all the polyolefin copolymers encompassed by the composition (B).

The polymer composition (B), in a further aspect of the present invention, is used to produce a film for encapsulation of an electronic device, especially a solar cell.

In this case, the composition (B) is first produced by mixing the composition (A) and the particular additives and the polyolefin copolymer. This is especially effected by adding the additives in liquid form, i.e. in pure form or as a solution in a solvent, to the composition (B) in a mixer. This is followed by stirring or keeping the mixture in motion until the liquid has been completely absorbed by the polymer pellets. Any solvents used are then removed again by applying a vacuum.

In a second step, the polymer formulation is extruded by means of an extruder to give a film. In this case, the composition (B) is metered continuously through a metering screw into an extruder in which the polymer is melted and the additives are distributed homogeneously in the polymer matrix by the kneading of the mixture. At the end of the extruder, the melt is passed through a slot die. Downstream of the nozzle, the film is drawn off by means of a roller system, cooled and rolled up.

Alternatively, the additives or the additive mixture can also be metered directly into the film extruder via the filling stub or via a side feed.

The examples which follow are intended to further illustrate the present invention, without any intention that it be restricted to these examples.

Having generally described this invention, a further understanding can be obtained by reference to certain specific examples which are provided herein for purposes of illustration only, and are not intended to be limiting unless otherwise specified.

### EXAMPLES

Abbreviations Used

ethylene glycol dimethacrylate=EGDMA;

γ-methacryloyloxypropyltrimethoxysilane=KBM;

triallyl isocyanurate=TAIC;

tert-butyl peroxy-2-ethylhexylcarbonate=TBPEHC.

Chemicals Used

EGDMA (CAS: 97-90-5) was sourced from Sigma Aldrich.

The triallyl isocyanurate used hereinafter was “TAICROS®” from Evonik Industries AG.

The γ-methacryloyloxypropyltrimethoxysilane used hereinafter was “Dynasylan Memo®” from Evonik Industries AG.

The EDA used hereinafter was “EVATANE 28-40” ® from Arkema having a vinyl acetate content of 28.3% by weight.

The tert-butyl peroxy-2-ethylhexylcarbonate (=“TBPEHC”) used hereinafter was sourced from United Initiators.

1. Production of the EVA pellets

### Comparative Example C1

2.5 g (10.0 mmol) of TAIC, 0.5 g of KBM and 4.0 g of TBPEHC were mixed homogeneously. This mixture was distributed homogeneously over 493 g of EVA. The EVA additive mixture was subsequently mixed in a tumbling mixer for 2 to 4 h.

### Inventive Examples 1-3

### Example 1

A mixture of 0.05 g (0.25 mmol) of EGDMA, 2.45 g (9.83 mmol) of TAIC, 0.5 g of KBM and 4.0 g of TBPEHC was distributed homogeneously over 493 g of EVA. The EVA additive mixture was subsequently mixed in a tumbling mixer for 2 to 4 h.

### Example 2

A mixture of 0.1 g (0.5 mmol) of EGDMA, 2.4 g (9.63 mmol) of TAIC, 0.5 g of KBM and 4.0 g of TBPEHC was distributed homogeneously over 493 g of EVA. The EVA additive mixture was subsequently mixed in a tumbling mixer for 2 to 4 h.

### Example 3

A mixture of 0.15 g (0.76 mmol) of EGDMA, 2.35 g (9.43 mmol) of TAIC, 0.5 g of KBM and 4.0 g of TBPEHC was distributed homogeneously over 493 g of EVA. The EVA additive mixture was subsequently mixed in a tumbling mixer for 2 to 4 h.

2. Film Extrusion

For production of the EVA films, the conditioned EVA pellets which had been prepared as in Examples C1 and 1-3 were metered volumetrically into a twin-screw laboratory extruder (Collin). The EVA melt was extruded through a slot die (10 cm) having adjustable gap width, the film was cooled continuously in a roller system to 20° C. and then rolled up. The extruder settings are listed below:

Extrusion parameters for EVA film production

Heating zone temperatures [° C.]

| | |
|---|---|
| T1 | 70 |
| T2 | 77 |
| T3 | 77 |
| T4 | 75 |
| T5 | 80 |
| Die | 80 |

3. Film Lamination

The lamination of the EVA film was conducted at 150° C. (machine setting) between Teflon release films, and the same temperature was kept constant over the entire lamination process. The duration of the one-stage devolatilization step was 100 s. Subsequently, the sample was subjected to a contact pressure of 0.7 kg/cm². The residence time in the laminator was 20 minutes.

4. Determination of Specific Resistance ρ

For the determination of the resistivity of crosslinked EVA films of thickness 400 to 500 μm, samples having dimensions of about 8×8 cm were first stored at room temperature (22.5° C.) and a relative air humidity of 50% for 7 days in order to assure a constant moisture level within the EVA film.

The resistivity measurement was conducted with a Keithley ohmmeter (6517B) and a corresponding test cell, likewise from Keithley (“resistivity test fixture 8009”). In accordance with ASTM D-257, the sample was subjected to a voltage of 500 V for 60 s and the current was measured after this time. The resistivity ρ (VR) can then be calculated from the known parameters.

Table 1 below summarizes the results observed.

TABLE 1

| | | | Proportion of | |
|---|---|---|---|---|
| | | | co-crosslinker | |
| Example | TAIC | EGDMA | based on | VR * 10¹⁵ |
| No. | [mmol] | [mmol] | TAIC [mol %] | [ohm * cm] |
| C1 | 10.0 | | | 3.77 |
| 1 | 9.83 | 0.25 | 2.5 | 4.82 |
| 2 | 9.63 | 0.50 | 5.2 | 8.08 |
| 3 | 9.43 | 0.76 | 8.1 | 8.56 |

The results shown in Table 1 demonstrate that the combination of TAIC and EGDMA results in a distinct increase in specific resistance. The specific resistance thus obtained is even higher than that achieved with conventional co-crosslinkers.

European patent application EP14199266 filed Dec. 19, 2014, is incorporated herein by reference.

Numerous modifications and variations on the present invention are possible in light of the above teachings. It is therefore to be understood that within the scope of the appended claims, the invention may be practiced otherwise than as specifically described herein.

1. A composition (A), comprising:
(i) at least one compound (I) selected from the group consisting of triallyl isocyanurate, and triallyl cyanurate; and
(ii) at least one compound of the chemical structure (II) with 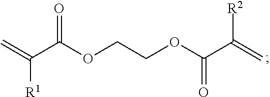
wherein R¹, R² are each independently H or methyl,
and wherein the proportion of all the compounds of the chemical structure (II) in the composition (A), based on all the compounds (I) in the composition (A), is in the range of 0.01 mol % to 13.5 mol %.

2. The composition (A) according to claim 1, wherein the compound (I) is triallyl isocyanurate.

3. The composition (A) according to claim 1, wherein R¹ and R² are the same.

4. The composition (A) according to claim 3, wherein R¹=R²=methyl.

5. The composition (A) according to claim 1, in which the proportion of all the compounds of the chemical structure (II), based on all the compounds of the chemical structure (I), is in the range of 0.05 mol % to 12.0 mol %.

6. The composition (A) according to claim 5, in which the proportion of all the compounds of the chemical structure (II), based on all the compounds of the chemical structure (I), is in the range of 2.5 mol % to 5.2 mol %.

7. A composition (B), comprising:
at least one polyolefin copolymer; and
a composition (A) according to claim 1.

8. The composition (B) according to claim 7, wherein the polyolefin copolymer is an ethylene-vinyl acetate copolymer.

9. The composition (B) according to claim 8, wherein the ethylene-vinyl acetate copolymer has a vinyl acetate content of 15% to 50% by weight, based on the total weight of the ethylene-vinyl acetate copolymer, determined to ASTM D 5594:1998.

10. The composition (B) according to claim 7, in which the proportion of composition (A) is 0.05% to 10% by weight, based on the mass of all the polyolefin copolymers encompassed by the composition (B).

11. The composition (B) according to claim 7, further comprising at least one initiator selected from the group consisting of peroxidic compounds, azo compounds, photoinitiators.

12. The composition (B) according to claim 11, wherein the initiator is a peroxidic compound.

13. The composition (B) according to claim 7, further comprising at least one compound (D) selected from the group consisting of crosslinkers, silane coupling agents, antioxidants, ageing stabilizers, metal oxides, metal hydroxides, and white pigments.

14. The composition (B) according to claim 13, wherein the compound (D) is a silane coupling agent.

15. A film for encapsulation of an electronic device, comprising: the composition (B) according to claim 7 in crosslinked form.

16. The film according to claim 15, wherein the device is a solar cell.

17. A method for encapsulating an electronic device, comprising:
contacting said electronic device with the composition (B) of claim 7 and crosslinking said composition (B).

18. The method according to claim 17, wherein the device is a solar cell.

19. The method according to claim 18, wherein the crosslinking of the composition (B) occurs in the course of solar module lamination.
